(19) United States
(12) Patent Application Publication
(10) Pub. No.: US 2015/0187745 A1
(43) Pub. Date: Jul. 2, 2015

(54) SOLDER PILLARS FOR EMBEDDING SEMICONDUCTOR DIE

(71) Applicants: SANDISK SEMICONDUCTOR (SHANGHAI) CO., LTD., Shanghai (CN); SANDISK INFORMATION TECHNOLOGY (SHANGHAI) CO., LTD., Shanghai (CN)

(72) Inventors: Chin-Tien Chiu, Taichung City (TW); Suresh Upadhyayula, San Jose, CA (US); EnYong Tai, Shanghai (CN); Dacheng Huang, Shanghai (CN); Yuang Zhang, Shanghai (CN)

(73) Assignees: SANDISK SEMICONDUCTOR (SHANGHAI) CO., LTD., Shanghai (CN); SANDISK INFORMATION TECHNOLOGY (SHANGHAI) CO., LTD., Shanghai (CN)

(21) Appl. No.: 14/561,689

(22) Filed: Dec. 5, 2014

(30) Foreign Application Priority Data
Dec. 31, 2013 (CN) 201310750904.1

(51) Int. Cl. H01L 25/18; H01L 23/31; H01L 23/00

(52) U.S. Cl. CPC H01L 25/18; H01L 24/17; H01L 23/3142; H01L 2924/014; H01L 2224/17151; H01L 2924/1438; H01L 2924/143; H01L 2224/16113; H01L 2224/16227; H01L 2224/16147; H01L 2224/16059; H01L 2224/16058; H01L 2224/16056

(57) ABSTRACT

A semiconductor device, and a method of its manufacture, are disclosed. The semiconductor device includes a semiconductor die, such as a controller die, mounted on a surface of a substrate. Pillars, for example of solder, may also formed on the substrate, around the semiconductor die. The pillars are formed to a height above the substrate that is greater than the height of the substrate-mounted semiconductor die, including any wire bonds, above the substrate. A second group of one or more semiconductor die, such as flash memory die, may be affixed to the substrate, on top of the solder pillars without contacting the substrate-mounted semiconductor die.

### BACKGROUND

The strong growth in demand for portable consumer electronics is driving the need for high-capacity storage devices. Non-volatile semiconductor memory devices, such as flash memory storage cards, are becoming widely used to meet the ever-growing demands on digital information storage and exchange. Their portability, versatility and rugged design, along with their high reliability and large capacity, have made such memory devices ideal for use in a wide variety of electronic devices, including for example digital cameras, digital music players, video game consoles, PDAs and cellular telephones.

While many varied packaging configurations are known, flash memory storage cards may in general be fabricated as system-in-a-package (SiP) or multichip modules (MCM), where a plurality of die are mounted and interconnected on a small footprint substrate. The substrate may in general include a rigid, dielectric base having a conductive layer etched on one or both sides. Electrical connections are formed between the die and the conductive layer(s), and the conductive layer(s) provide an electric lead structure for connection of the die to a host device. Once electrical connections between the die and substrate are made, the assembly is then typically encased in a molding compound which provides a protective package.

A cross-sectional side view and a top view of a conventional semiconductor package 20 are shown in FIGS. 1 and 2 (without molding compound in FIG. 2). Typical packages include a plurality of semiconductor die, such as flash memory die 22 and a controller die 24, affixed to a substrate 26. A plurality of die bond pads 28 may be formed on the semiconductor die 22, 24 during the die fabrication process. Similarly, a plurality of contact pads 30 may be formed on the substrate 26. Die 22 may be affixed to the substrate 26, and then die 24 may be mounted on die 22. All die may then be electrically coupled to the substrate by affixing wire bonds 32 between respective die bond pad 28 and contact pad 30 pairs. Once all electrical connections are made, the die and wire bonds may be encapsulated in a molding compound 34 to seal the package and protect the die and wire bonds.

In order to most efficiently use package footprint, it is known to stack semiconductor die on top of each other, either completely overlapping each other, or with an offset as shown in FIGS. 1 and 2. In an offset configuration, a die is stacked on top of another die so that the bond pads of the lower die are left exposed. An offset configuration provides an advantage of convenient access of the bond pads on each of the semiconductor die in the stack. While two memory die are shown in the stack in FIG. 1, it is known to provide more memory die in the stack, such as for example four or eight memory die.

In order to increase memory capacity in semiconductor packages while maintaining or reducing the overall size of the package, the size of the memory die has become large compared to the overall size of the package. As such, it is common for the footprint of the memory die to be almost as large as the footprint of the substrate.

The controller die 24 is generally smaller than the memory die 22. Accordingly, the controller die 24 is conventionally placed at the top of the memory die stack. This configuration has certain drawbacks. For example, is difficult to form a large number of wire bonds from the die bond pads on the controller die down to the substrate. It is known to provide an interposer or redistribution layer beneath the controller die so that wire bonds are made from the controller die to the interposer, and then from the interposer down to the substrate. However, this adds cost and complexity to the semiconductor device fabrication. Moreover, the relatively long length of the wire bonds from the controller die to the substrate slows down operation of the semiconductor device.

### DESCRIPTION OF THE DRAWINGS

FIG. 1 is a prior art edge view of a conventional semiconductor device including a pair of semiconductor die stacked in an offset relation.

FIG. 2 is a prior art edge view of a conventional semiconductor device including a pair of semiconductor die stacked in an overlapping relation and separated by a solder pillars.

FIG. 3 is a flowchart for forming a semiconductor die according to embodiments of the present invention.

FIG. 4 is a perspective view of a stage in the fabrication of a semiconductor device according to an embodiment of the present technology.

FIG. 5 is a perspective view of a further stage in the fabrication of a semiconductor device according to an embodiment of the present technology.

FIG. 6 is a perspective view of a further stage in the fabrication of a semiconductor device according to an embodiment of the present technology.

FIG. 7 is a perspective view of another stage in the fabrication of a semiconductor device according to an embodiment of the present technology.

FIG. 8 is a perspective view of a further stage in the fabrication of a semiconductor device according to an embodiment of the present technology.

FIGS. 9 and 10 are perspective and edge views of further stages in the fabrication of a semiconductor device according to an embodiment of the present technology.

FIGS. 11 and 12 are perspective and edge views of further stages in the fabrication of a semiconductor device according to an embodiment of the present technology.

FIG. 13 is a partial edge view of solder pillars according to an alternative embodiment of the present technology.

FIGS. 14-16 are perspective views of solder pillars on a substrate according to alternative embodiments of the present technology.

FIG. 17 is flowchart for forming solder pillars on a semiconductor wafer according to an alternative embodiment of the present technology.

FIG. 18 is a perspective view of a semiconductor wafer including solder pillars according to the flowchart of FIG. 17.

FIG. 19 is a single semiconductor die from the wafer of FIG. 17.

FIGS. 20 and 21 are edge views of stages in the fabrication of a semiconductor device made according to the alternative embodiment of FIGS. 17-19.

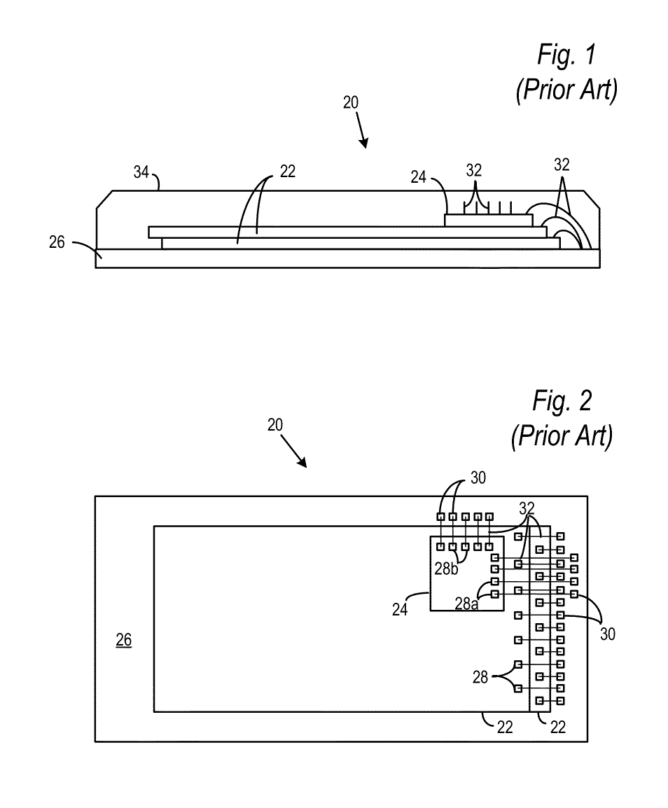

### DETAILED DESCRIPTION

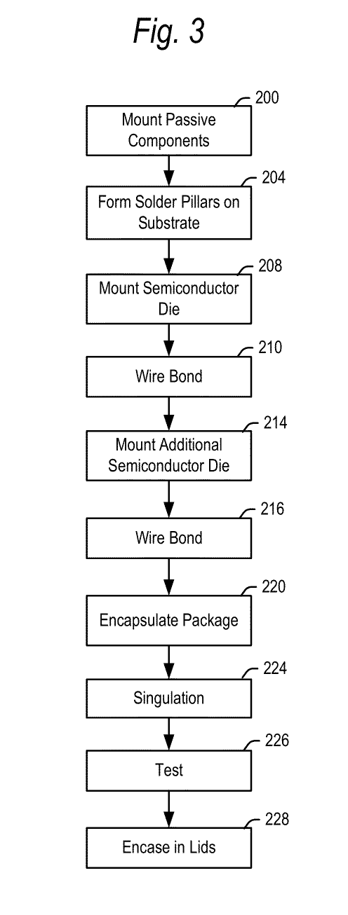

The present technology will now be described with reference to FIGS. 3 through 21, which in embodiments, relate to a semiconductor device including a first semiconductor die, such as a controller, mounted on a surface of a substrate. Pillars, for example of solder, may also formed on the substrate, around the semiconductor die. The pillars are formed to a height above the substrate that is greater than the height of the substrate-mounted semiconductor die, including any wire bonds, above the substrate. A second group of one or more semiconductor die, such as flash memory die, may be affixed to the substrate, on top of the solder pillars without contacting the substrate-mounted semiconductor die.

In an alternative embodiment, instead of being formed on the substrate to thereafter receive the second group of one or more semiconductor die, the pillars may instead be formed on the semiconductor wafer from which the bottommost die of the second group is formed. When the semiconductor wafer is diced, a pick and place robot may mount the bottommost die so that the pillars are positioned against the substrate, thus spacing the bottommost die above the substrate-mounted semiconductor die.

It is understood that the present invention may be embodied in many different forms and should not be construed as being limited to the embodiments set forth herein. Rather, these embodiments are provided so that this disclosure will be thorough and complete and will fully convey the invention to those skilled in the art. Indeed, the invention is intended to cover alternatives, modifications and equivalents of these embodiments, which are included within the scope and spirit of the invention as defined by the appended claims. Furthermore, in the following detailed description of the present invention, numerous specific details are set forth in order to provide a thorough understanding of the present invention. However, it will be clear to those of ordinary skill in the art that the present invention may be practiced without such specific details.

The terms “top” and “bottom,” “upper” and “lower” and “vertical” and “horizontal” as may be used herein are by way of example and illustrative purposes only, and are not meant to limit the description of the invention inasmuch as the referenced item can be exchanged in position and orientation. Also, as used herein, the terms “substantially” and/or “about” mean that the specified dimension or parameter may be varied within an acceptable manufacturing tolerance for a given application. In one embodiment, the acceptable manufacturing tolerance is ±0.25%.

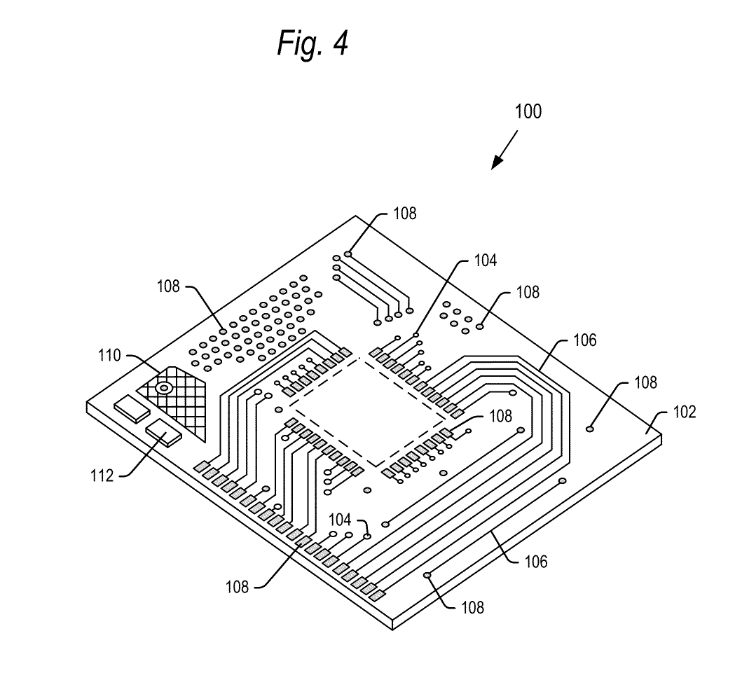

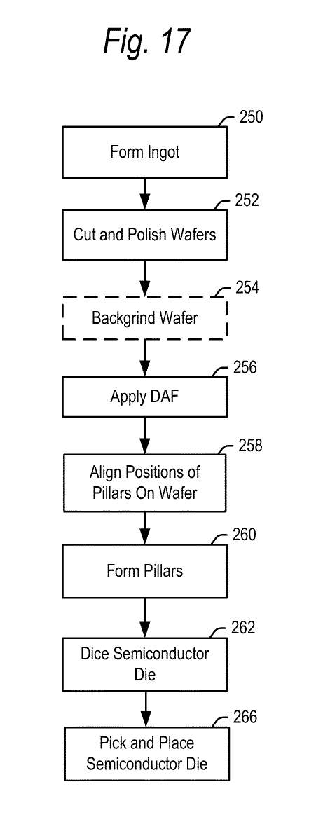

An embodiment of the present invention will now be explained with reference to the flowcharts of FIGS. 3 and 17, and the views of FIGS. 4-16 and 18-21. Although the figures show an individual semiconductor device 100, or a portion thereof, it is understood that the device 100 may be batch processed along with a plurality of other devices 100 on a substrate panel to achieve economies of scale. The number of rows and columns of semiconductor devices 100 on the substrate panel may vary.

The substrate panel may begin with a plurality of substrates 102 (again, one such substrate is shown in FIGS. 4-16 for example). The substrate 102 may be a variety of different chip carrier mediums, including a printed circuit board (PCB), a leadframe or a tape automated bonded (TAB) tape.

Referring to FIG. 4, the substrate may include a plurality of vias 104, electrical traces 106 and contact pads 108. The substrate 102 may include more or less vias 104, traces 106 and/or contact pads 108 (only some of which are numbered in the figures) than are shown. The contact pads 108 are shown as shaded rectangles and circles in the figures (whereas vias are shown as circles without shading). The vias 104, traces 106 and contact pads 108 may be in different locations than are shown in the figures in further embodiments. FIG. 4 further illustrates a dummy circuit pattern 110 for preventing thermal mismatch across the surface of the substrate 102.

Referring to the flowchart of FIG. 3, passive components 112 may be affixed to the substrate 102 in a step 200. The one or more passive components may include for example one or more capacitors, resistors and/or inductors, though other components are contemplated. The passive components 112 shown (only one of which is numbered in the figures) are by way of example only, and the number, type and position may vary in further embodiments.

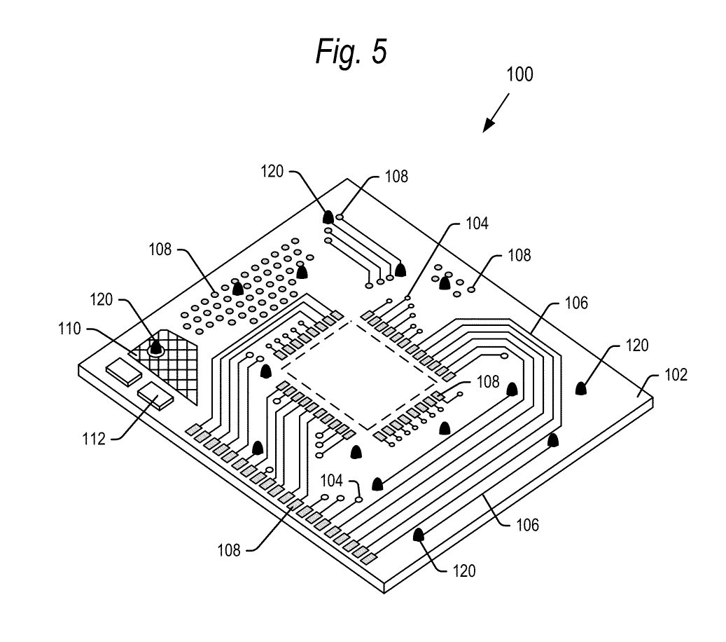

In step 204, solder pillars 120 (some of which are numbered) may be formed on the surface of the substrate 102 as shown in FIG. 5. The number and position of solder pillars 120 are shown by way of example only, and as explained below may vary in further embodiments of the present technology. However, in one example, solder pillars may be applied to a number of contact pads 108 as preformed solder balls or as solder paste which is subsequently cured. In one example, the solder pillars may be formed of tin, though other materials such as gold, aluminum or copper are contemplated. In embodiments, the solder pillars may be formed of a dielectric material, or have dielectric additives to make the solder pillars electrically non-conductive.

Where solder balls are used for solder pillars 120, the solder balls may be of known construction and applied in a solder ball placement process. In one example, the solder balls may extend between 30 μm to 200 μm above the surface of substrate 102, and in a further embodiment, 120 μm above the surface of the substrate. However, it is understood that these numbers are by way of example only, and the height of the solder balls above the surface may be lesser or greater than this in further embodiments. The solder balls may be cured onto the contact pads 108 by heating the solder balls to a temperature above the melting point of the of the solder balls (221° C. in one example) for a period of 30 to 60 seconds, with a peak temperature of between 245° C. and 255° C. These time and temperatures are by way of example only and may vary in further embodiments.

Where solder paste is used for the solder pillars 120, the solder paste may be applied to contact pads 108 in a known screen printing process. As is known, such a solder printing process may include application of paste including micro solder balls (having a diameter of for example approximately 10 μm to 50 μm) suspended in a liquid flux material to contact pads 108. The solder paste may thereafter be cured into the solidified solder pillars in a heating process such as for example an IR-reflow process to heat the solder paste above melting (221° C. in one example) for a period of 30 to 60 seconds, with a peak temperature of between 245° C. and 255° C. These time and temperatures are by way of example only and may vary in further embodiments. Once solidified, the solder paste pillars may each extend between 30 μm to 200 μm above the surface of substrate 102, and in a further embodiment, 120 μm above the surface of the substrate. It is understood that these numbers are by way of example only, and the height of the solder paste pillars above the surface may be lesser or greater than this in further embodiments.

It is further contemplated that other structurally rigid materials may be used instead of solder paste or solder balls has pillars 120. Such structurally rigid materials may be structurally rigid when applied to substrate 100, or may become structurally rigid after a heating or curing process, and may function in the same manner as solder pillars formed of solder balls or solder paste, as explained below.

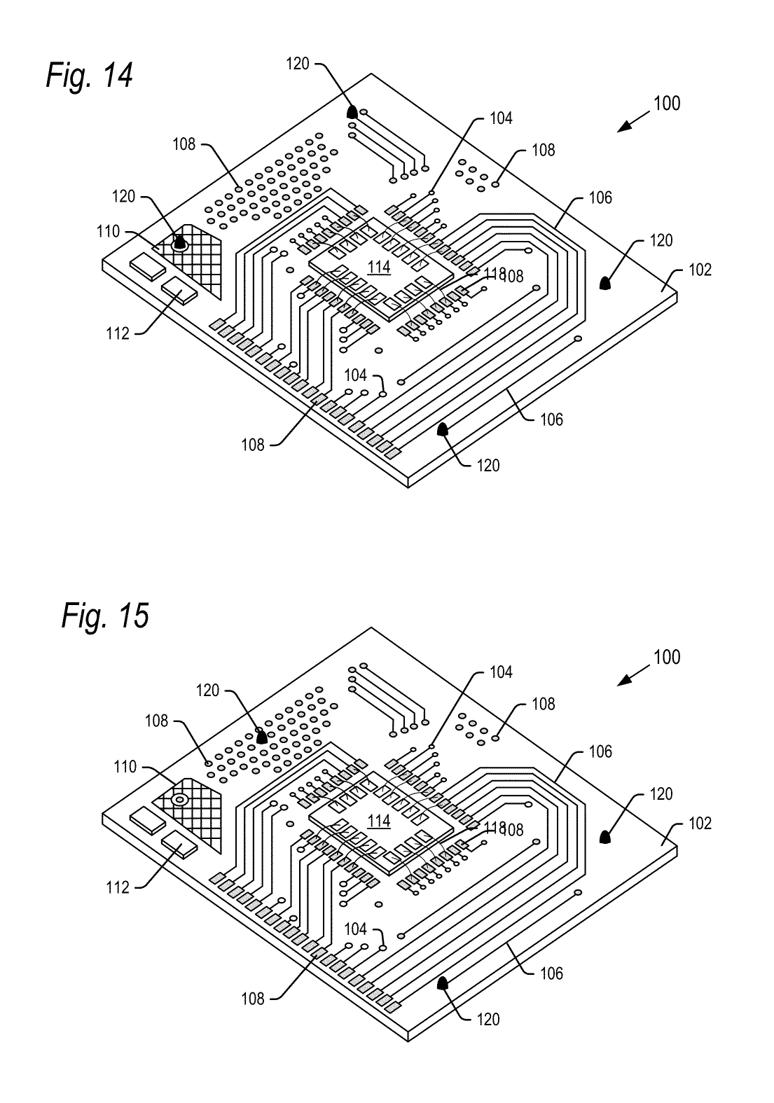

As seen in the perspective view of FIG. 5, in one embodiment, solder pillars 120 may be provided at positions so as to be relatively evenly distributed on contact pads 108 over a surface of the substrate 102. In the example illustrated in FIG. 5, there are 15 solder pillars 120. Is understood that there may be hundreds of solder pillars 120 in further embodiments, as few as three or four solder pillars, or any number in between, as explained in greater detail hereinafter with respect to FIGS. 14-16. The solder pillars may be arranged in a variety of other patterns on substrate 102 in alternative embodiments.

The solder pillars 120 may be applied to active contact pads 108, meaning such contact pads 108 serve some electrical function, such as for example serving as power, ground and/or signal conduits. The solder pillars 120 may alternatively or additionally be applied to inactive contact pads 108 which otherwise do not carry signals, power or a path to ground.

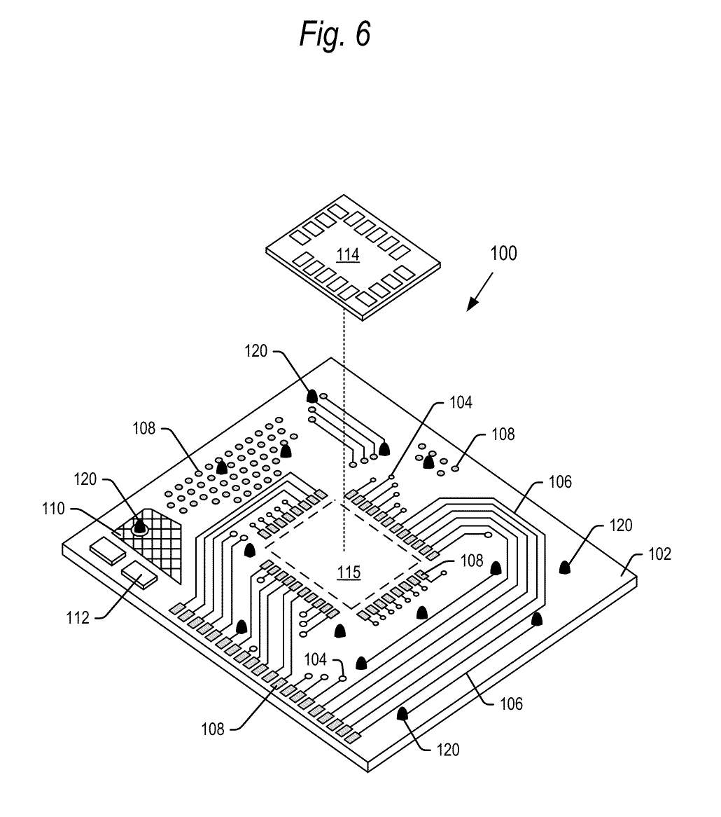

In step 208, a semiconductor die 114 may be mounted on a surface of the substrate 102 as indicated in FIG. 6. The surface-mounted semiconductor die 114 may be positioned on the substrate 102 within an area 115 that is devoid of solder pillars 120, such as for example in a center of substrate 102. The semiconductor die 114 may be a controller ASIC. However, die 114 may be other types of semiconductor die, such as a DRAM or NAND.

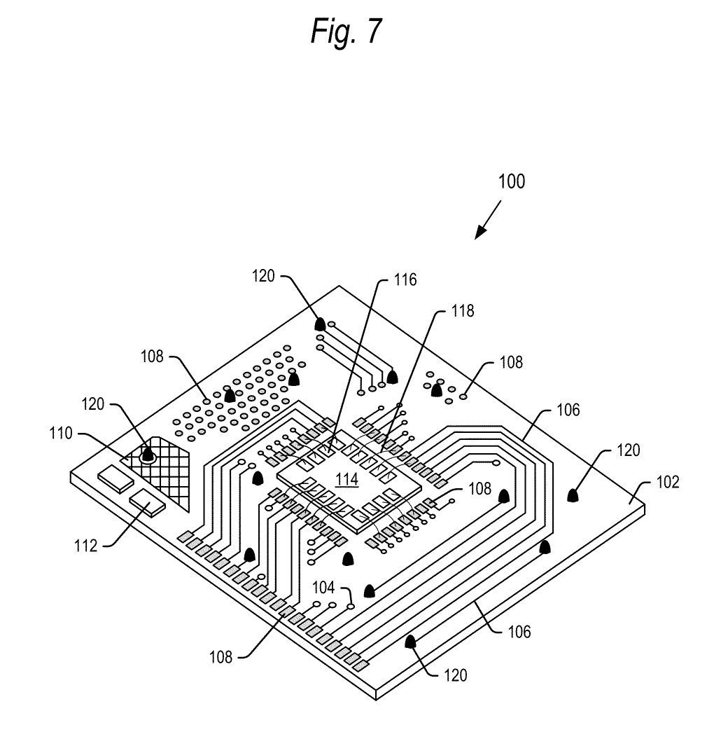

FIG. 7 shows the semiconductor die 114 mounted on the substrate 102. The semiconductor die 114 includes die bond pads 116, one of which is labeled for example in FIG. 7. The number of die bond pads 116 shown is for clarity only, and it is understood that there may be more contact pads 108 and die bond pads 116 in further embodiments. Moreover, while semiconductor die 114 is shown with die bond pads 116 on four sides in FIG. 7, it is understood that semiconductor die 114 may have die bond pads 116 on one, two or three sides of the semiconductor die 114 in further embodiments.

In embodiments, the semiconductor die 114 may have a thickness of 46 μm, and attached to the substrate with a die attach film having a thickness of 10 μm, though these thicknesses may vary. The solder pillars 120 may each have a height above the surface of the substrate 102 so as to be higher off the substrate surface than the thickness of the semiconductor die 114 and die attach film, together with any wire bonds off of the semiconductor die 114. As noted above, the solder pillars 120 may be 120 μm high in one example.

In step 210, the die bond pads 116 on semiconductor die 114 may be electrically coupled to contact pads 108 on the substrate 102 via wire bonds 118, one of which is numbered in FIG. 7. Wire bonding may be performed by a wire bond capillary (not shown) forming the wire bonds 118. It is understood that the semiconductor die 114 may be electrically coupled to the substrate 102 using technologies other than wire bonding. For example, semiconductor die 114 may be a flip-chip which is soldered onto contact pads of the substrate 102. As a further example, conductive leads may be printed by known printing processes between the die bond pads and contact pads to electrically couple the semiconductor die 114 to the substrate 102.

It is understood that order of the steps of forming the solder pillars (step 204), mounting the semiconductor die 114 (step 208) and wire bonding the semiconductor 114 (step 210) may be performed in different orders in further embodiments. For example, the semiconductor die 114 may be mounted and wire bonded and thereafter, the solder pillars 120 formed on the substrate. As a further example, the semiconductor die 114 may be mounted, the solder pillars formed, and thereafter, the semiconductor die 114 may be wire bonded.

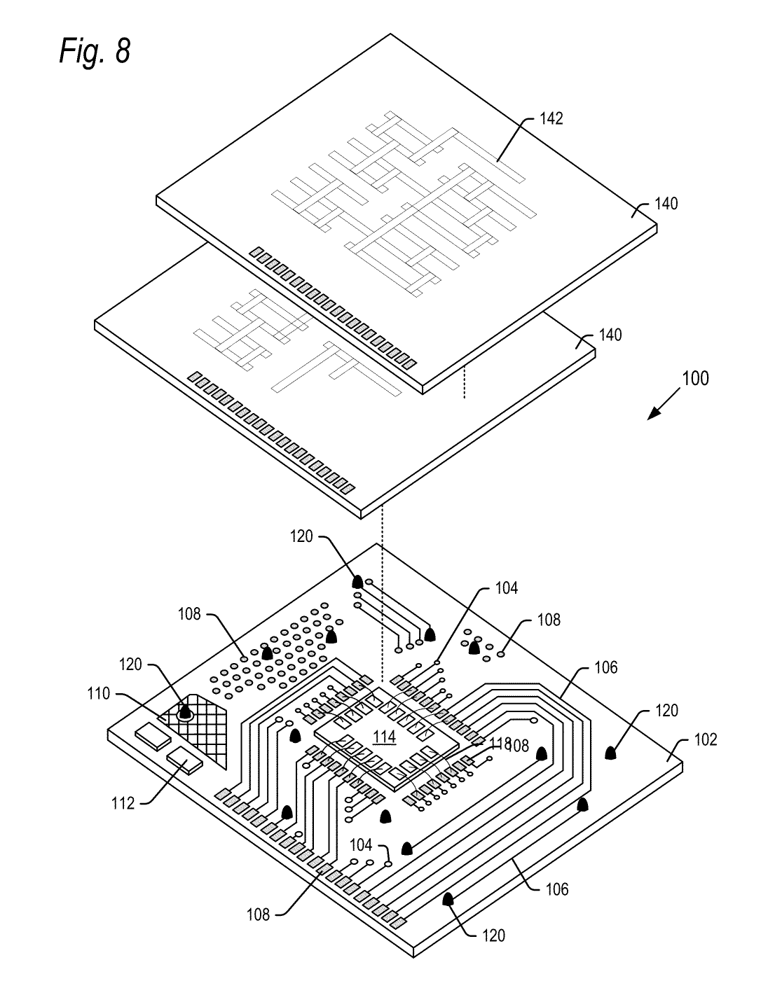

In step 214, one or more semiconductor die 140 may be stacked on top of the solder pillars 120 as shown in FIGS. 8-10. The semiconductor die 140 may be stacked in stepped configuration. While two such semiconductor die 140 are shown, there may be a single semiconductor die 140 or more than two semiconductor die in the die stack in further embodiments. Semiconductor die 140 may include integrated circuits 142 functioning for example as memory die and more preferably NAND flash memory die, but other types of semiconductor die are contemplated.

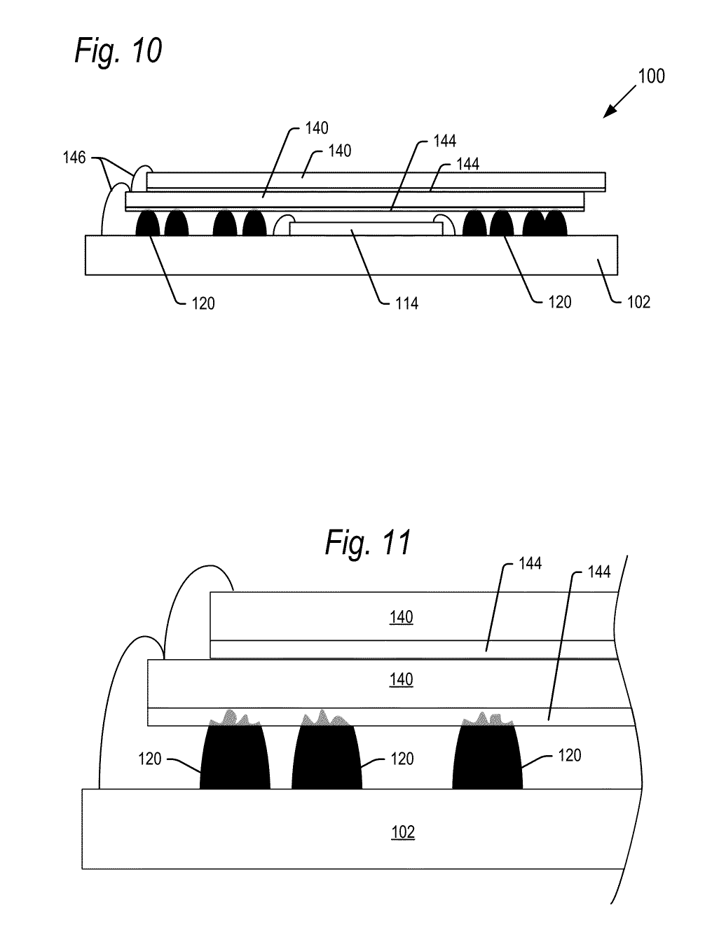

As seen for example in FIGS. 10-13, the bottommost semiconductor die 140 may be affixed to the substrate as a result of being supported on the upper surfaces of the solder pillars 120 (upper surfaces being the surfaces of the solder pillars opposite the surface in contact with the substrate 102). As discussed above, the solder pillars 120 extend a greater distance above the substrate 102 than the semiconductor die 114 and wire bonds so that the semiconductor die 140 may be mounted on the pillars 120 without contacting the semiconductor die 114 or wire bonds. Additionally, the distribution of solder pillars 120 on the substrate 102 provides generally planar support for the semiconductor die 140.

In embodiments, the solder pillars (solder balls or solder paste) are fabricated so that each solder pillar 120 extends to the same height above the surface of the substrate 102. This provides a generally planar support for the semiconductor die 140 mounted on the solder pillars.

However, it is understood that the pillars 120 need not each extend above the surface of the substrate to the same height, for example varying within the manufacturing tolerances of the solder pillars. The solder pillars 120 embed within a layer of die attach film on the bottom surface of the bottommost die 140, as explained below. The embedding of the solder pillars 120 in the die attach film allows for differences in solder pillar heights. In particular, different height solder pillars may embed in the die attach film layer to differing extents, thereby providing planar support as a whole for the semiconductor die 140 mounted thereon.

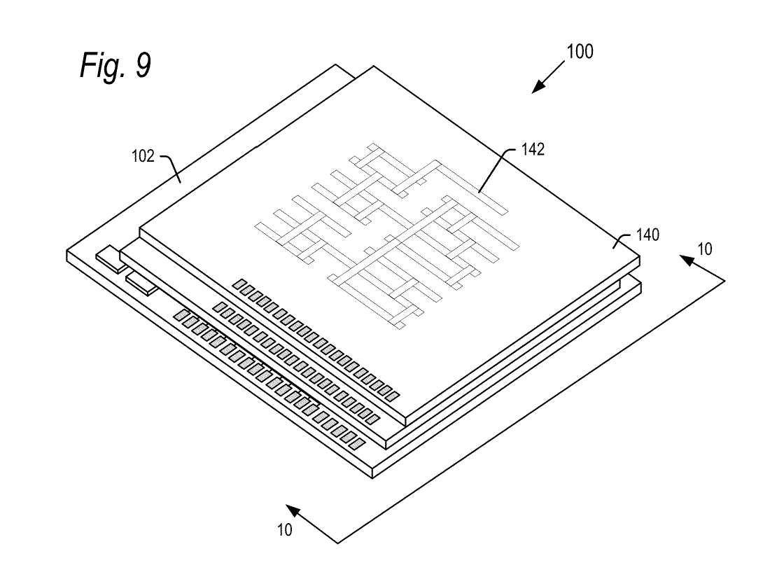

In embodiments, a layer of die attach film (DAF) 144 may be applied to the bottom surfaces of the semiconductor die 140. The DAF 144 serves to attach the semiconductor die 140 in the die stack to each other. Additionally, upon positioning the bottommost die 140 on the substrate, the upper surfaces of the solder pillars 120 embed within the DAF 144 on the bottommost semiconductor die 140. FIG. 10 is an edge view through line 10-10 of FIG. 9. FIG. 10 illustrates the upper surfaces of solder pillars 120 embedded within the DAF layer 144 of the bottommost semiconductor die 140. This serves to affix the bottommost die 140, and those mounted thereon, in position on the substrate 102, and to resist shear forces exerted on the die 140 during the encapsulation process, explained in greater detail below.

In embodiments, DAF 144 may be available from Nitto Denko Corp. of Japan, and may have a thickness of between 20 and 25 μm, though it may be thinner or thicker than that in further embodiments. A thicker DAF layer may add height to the semiconductor device 100, but may also allow better adhesion between the solder pillars 120 and the DAF 144, and better dissipation of the shear forces during encapsulation.

The surfaces of the pillars 120 that embed within the DAF layer 144 may be flat or rounded. It is also conceivable that the shape of these surfaces of the solder pillars 120 may be jagged, edged and/or otherwise irregular to improve the bond between the solder pillars 120 and the DAF 144. FIG. 11 shows an enlarged partial view of solder pillars 120 according to such embodiment embedded within the DAF 144 of the bottommost semiconductor die 140.

In step 216, the semiconductor die 140 may be wire bonded to contact pads 108 on the substrate 102 via wire bonds 146 in a known wire bonding process, using for example a wire bond capillary (not shown) as shown in FIG. 10.

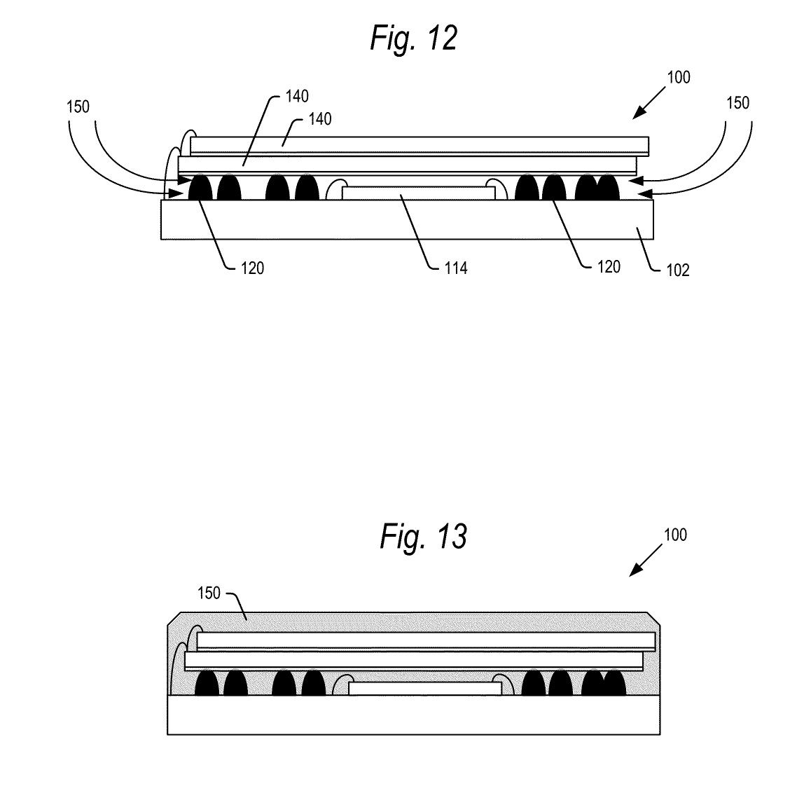

After the die stack is formed and wire bonded to contact pads 108 on the substrate 102, the semiconductor device 100 may be encased within the molding compound 150 in step 220 as shown in FIGS. 12 and 13. As indicated in FIG. 12, once the semiconductor device 100 is positioned between upper and lower mold plates (not shown), liquid molding compound 150 may be injected around and into the semiconductor device 100. In particular, molding compound 150 may be injected between the substrate 102 and the bottommost semiconductor die 140 into the space defined by the solder pillars 120.

Once the molding compound 150 hardens, the molding compound encases and protects semiconductor die 114 on the substrate 102. It also fixes the position of the semiconductor die 140 in the semiconductor device 100, which semiconductor die 140 were to that point held in position as a result of the solder pillars 120 embedding within the DAF 144 of the bottommost semiconductor die 140.

Molding compound 150 may be a known epoxy such as for example available from Sumitomo Corp. and Nitto Denko Corp., both having headquarters in Japan. After step 220, the encapsulated packages maybe singulated from the substrate panel in step 224 to form the finished semiconductor device 100 shown in FIG. 13. Thereafter, the device 100 may undergo electrical test and burn-in in step 226. In some embodiments, the finished semiconductor device 100 may optionally be enclosed within a lid (not shown) in step 228.

As noted above, solder pillars 120 may be provided in various numbers and at various locations on the substrate 102. FIG. 14 shows an embodiment including four solder pillars 120 positioned on the substrate 102 to lie in contact generally with the four corners of the bottommost semiconductor die 140. FIG. 15 illustrates a further embodiment including three solder pillars 120. The three solder pillars 120 are sufficient to define a plane for supporting the semiconductor die 140 above the surface of substrate 102 and semiconductor die 114.

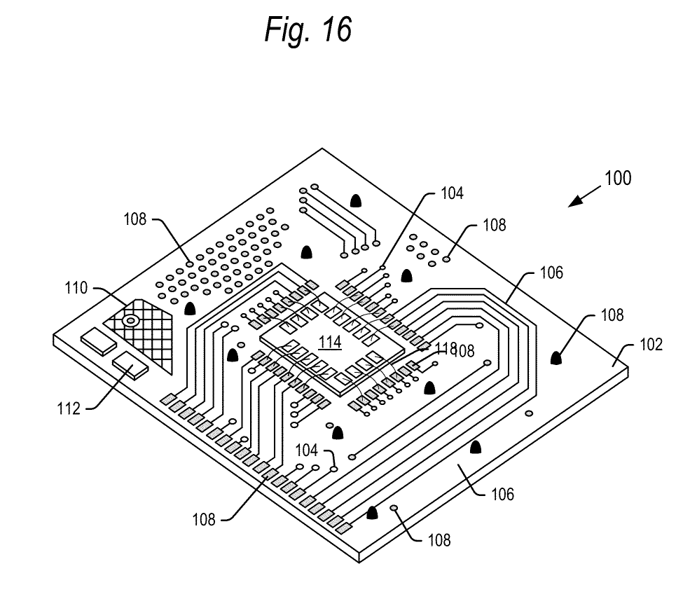

In the embodiments described above, solder pillars 120 are soldered onto contact pads 108. Given that the pillars 120 perform no electrical function, the pillars maybe affixed onto substrate 102 at locations other than contact pads 108 in further embodiments. An example of this is shown in FIG. 16. A layer of solder mask (not shown) may be formed on the surface of substrate 102 to cover areas of the substrate other than contact pads 108. The pillars 120 in this embodiment may be affixed to various positions on top of the solder mask. As noted above, pillars 120 may be formed of material other than solder in further embodiments.

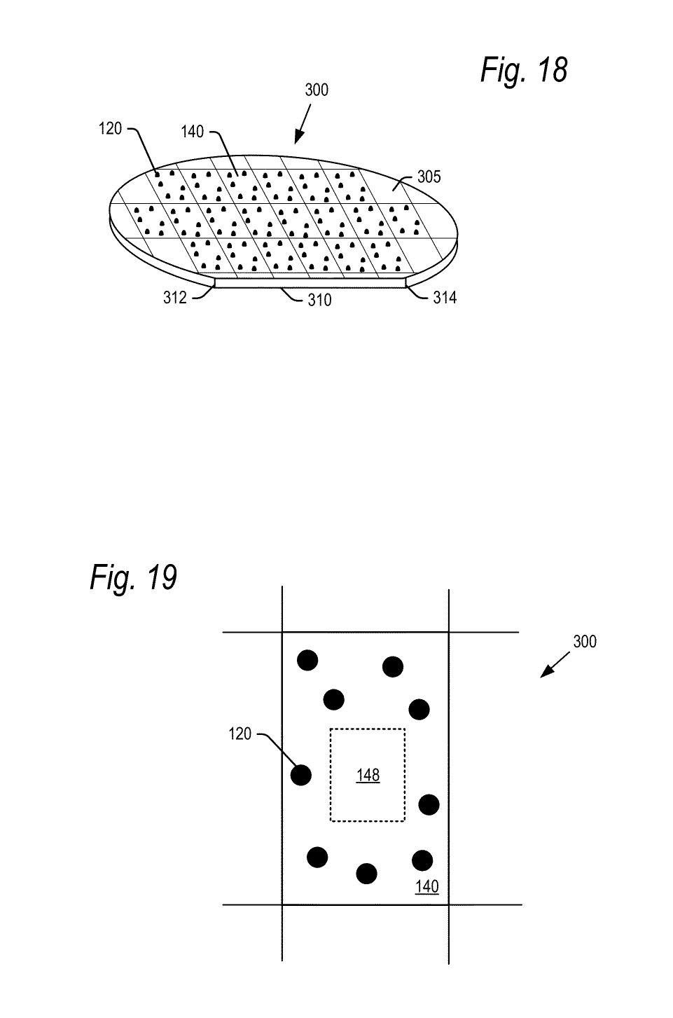

In the embodiments described above, the solder pillars 120 are formed on the substrate 102, and thereafter semiconductor die 140 are mounted thereon. In a further alternative embodiment, the solder pillars 120 may be formed on a surface of the semiconductor die 140 during processing of a wafer from which semiconductor die 140 is cut. Such an example is now described with reference to the flowchart of FIG. 17, and the illustrations of FIGS. 18-21.

Referring to FIG. 18, the bottommost semiconductor die 140 may be formed from semiconductor wafer 300. Semiconductor wafer 300 may start as an ingot of wafer material which may be formed in step 250. In one example, the ingot may be monocrystalline silicon grown according to either a Czochralski (CZ) or floating zone (FZ) process. It may be polycrystalline silicon in further embodiments.

In step 252, the semiconductor wafer 300 may be cut from an ingot and polished on both major surfaces to provide smooth surfaces. Wafer 300 may have a first major surface in which integrated circuits 144 are formed, and an opposite, second major surface 305 (FIG. 18). In step 254, a grinding wheel may be applied to the second major surface 305 to backgrind the wafer 300 from, for example, 780 μm to 280 μm, though these thicknesses are by way of example only and may vary in different embodiments. This step is shown in dashed lines as this step may be skipped in embodiments. A layer of DAF (such as DAF 144 described above) may be applied to surface 305 of the wafer 300 in step 256.

Pillars 120 are formed on the major surface 305 in step 260. Prior to formation of the pillars 120, the positions of the pillars to be formed may be aligned to the wafer in step 258. For example, the finished positions of the semiconductor die to be cut from the wafer 300 are known. The positions of the pillars 120 may be set so as to align in the same positions on each of the semiconductor die that are to be diced from the wafer. This alignment may be done by a number of different methods. In one example, reference positions may be defined on the wafer 300 and all positions of semiconductor die and pillars 120 may be defined in relation to these reference points.

For example, wafer 300 typically includes a flat 310 (FIG. 18) for identifying and orienting the crystalline structure of the wafer for processing. The flat 310 ends at points, referred to as cleave points 312, 314, where the rounded portion of the wafer 300 meets the flat 310. The positions of the semiconductor die 140 as diced may be defined relative to one or both cleave points 312, 314. Thereafter, the positions of the pillars 120 for each of the semiconductor die 140 may be aligned to the positions of the semiconductor die by positioning them at known distances along the x- and y-axes relative to the cleave points 312 and/or 314. Thus, each pillar 120 may be precisely positioned within each semiconductor die, for example positions to leave a center area 148 (FIG. 19) open within each die 140 when the die are diced from the wafer 300.

In step 260, pillars 120 are formed at the desired locations on the wafer 300. The pillars may be affixed into the DAF layer on the major surface 305. In embodiments, the pillars may be embedded into the DAF layer. In further embodiments, the pillars 305 may be mounted to the major surface 305, through the DAF layer, for example by known bump bonding techniques. The pillars 120 may be formed of tin or gold, though other materials are possible. The pillars 120 may have dimensions as described above.

After the pillars 120 are formed, the wafer 300 may be diced in step 262 into individual semiconductor die 140. The wafer 300 may be diced using a saw blade in a known dicing process.

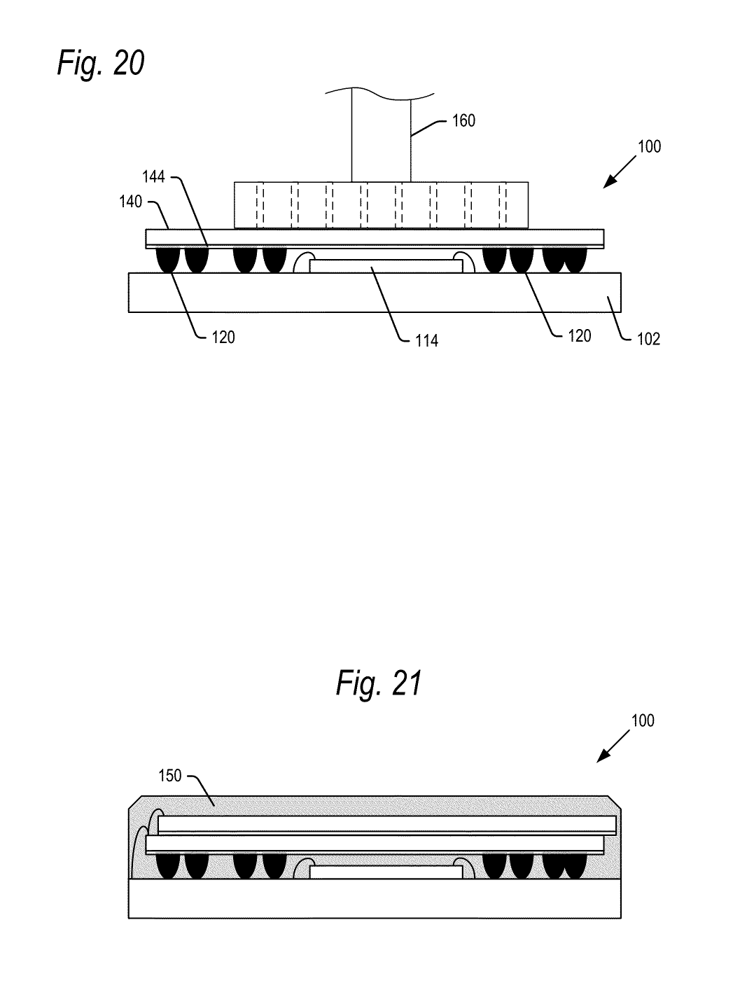

In the dicing step, the wafer 300 may be held on a wafer chuck (not shown) with the major surface 305 including the pillars 120 held against the wafer chuck. The wafer chuck may have a design allowing the wafer 300 to be securely held despite the presence of the pillars, for example forming a vacuum seal between the wafer and the chuck around an outer periphery of the wafer Thereafter, in step 266, a pick and place robot 160 (FIG. 20) having a vacuum tip may contact the major surface including integrated circuits 146 and remove the semiconductor die 140 from the vacuum chuck.

The pick and place robot 160 may place a semiconductor die 140 on the substrate 102 as shown in FIG. 20. A semiconductor die 114 may already be mounted and wire bonded to the substrate 102 as explained above. The pillars 120 on the die 140 may be positioned against a surface of the substrate 102, for example aligned against contact pads 108, and affixed thereto for example in an ultrasonic welding or other heating process.

One or more additional semiconductor die 140 may then be mounted to the bottommost semiconductor die 140 shown in FIG. 21 to form the die stack. These additional semiconductor die 140 may come from a wafer different than the wafer 300 shown in FIG. 19, and would not include pillars 120. The semiconductor die 140 in the die stack may thereafter be wire bonded to the substrate, and the semiconductor device 100 may be encapsulated with molding compound 150 as described above. The encapsulated packages may thereafter be singulated to form finished semiconductor devices 100 as shown in FIG. 21 and as also described above.

The semiconductor device 100 may be used as an LGA (land grid array) package so as to be used as removable memory within a host device. In such embodiments, contact fingers (not shown) may be formed on a lower surface of the substrate 102 for mating with pins in a host device upon insertion of the semiconductor device 100 in the host device. Alternatively, the semiconductor device 100 may be used as a BGA (ball grid array) package so as to be permanently affixed to a printed circuit board within a host device. In such embodiments, solder balls (not shown) may be formed on contact pads on a lower surface of the substrate 102 for being soldered onto a printed circuit board of a host device.

The solder pillars 120 allow the semiconductor die 114, for example a controller, to be mounted on the surface of the substrate 102, while providing a large, flat support plane for mounting of additional semiconductor die, for example memory die. Solder pillars 120 are also good thermal conductors to conduct heat away from the semiconductor die 114 and/or 140.

In summary, an example of the present technology relates to a semiconductor device, comprising: a substrate; a first semiconductor die mounted to a surface of the substrate and electrically connected to the substrate, the semiconductor die together with electrical connections extending a first height above the surface of the substrate; a plurality of pillars affixed around the first semiconductor die, the plurality of pillars extending a second height above the surface of the substrate, the second height being greater than the first height; a group of one or more second semiconductor die affixed on the plurality of pillars, the pillars supporting the group of one or more second semiconductor die above the first semiconductor die and electrical connections of the first semiconductor die to the substrate.

In another example, the present technology relates to semiconductor device, comprising: a substrate including contact pads; a first semiconductor die mounted to a surface of the substrate and electrically connected to the substrate; a plurality of solder pillars soldered to contact pads around the first semiconductor die; a group of one or more second semiconductor die affixed on the plurality of pillars, the pillars supporting the group of one or more second semiconductor die so as to space the group of one or more second semiconductor die away from the first semiconductor die and electrical connections of the first semiconductor die to the substrate

In a further example, the present technology relates to a semiconductor device, comprising: a substrate; a first semiconductor die mounted to a surface of the substrate and electrically connected to the substrate; a plurality of pillars having a first surface affixed to the substrate around the first semiconductor die and a second surface spaced away from the substrate; a group of one or more second semiconductor die, a semiconductor die of the group of one or more second semiconductor die including a layer of die attach film on a surface of the semiconductor die, the group of one or more second semiconductor die affixed to the substrate by the second surfaces of the plurality of pillars embedding in the die attach film on the surface of the semiconductor die of the group of one or more semiconductor die, the pillars supporting the group of one or more second semiconductor die with a space between the group of one or more second semiconductor die and the first semiconductor die including electrical connections of the first semiconductor die to the substrate.

The foregoing detailed description of the invention has been presented for purposes of illustration and description. It is not intended to be exhaustive or to limit the invention to the precise form disclosed. Many modifications and variations are possible in light of the above teaching. The described embodiments were chosen in order to best explain the principles of the invention and its practical application to thereby enable others skilled in the art to best utilize the invention in various embodiments and with various modifications as are suited to the particular use contemplated. It is intended that the scope of the invention be defined by the claims appended hereto.

We claim:

1. A semiconductor device, comprising:
a substrate;
a plurality of pillars affixed to the substrate;
a group of one or more semiconductor die;
a die attach film on a surface of one of the semiconductor die of the group of one or more semiconductor die, the plurality of pillars embedding within the die attach film to support the group of one or more semiconductor die above the substrate.

2. The semiconductor device of claim 1, the group of one or more semiconductor die comprising a group of one or more second semiconductor die, the device further comprising a first semiconductor die mounted to a surface of the substrate and electrically connected to the substrate, the first semiconductor die together with electrical connections fitting beneath the group of one or more second semiconductor die.

3. The semiconductor device of claim 1, wherein a surface of the plurality of pillars embedded within the die attach film layer has a flat, rounded, jagged, edged or irregular surface shape.

4. The semiconductor device of claim 1, further comprising molding compound, the molding compound securing the group of one or more second semiconductor die in relation to the substrate.

5. The semiconductor device of claim 1, wherein the plurality of pillars are made of solder.

6. The semiconductor device of claim 1, wherein the plurality of pillars are made of solder balls.

7. The semiconductor device of claim 1, wherein the plurality of pillars are made of solder paste.

8. The semiconductor device of claim 1, wherein the plurality of pillars are distributed across the surface of the substrate.

9. The semiconductor device of claim 1, wherein the plurality of pillars are four pillars.

10. The semiconductor device of claim 1, wherein the plurality of pillars are three pillars.

11. The semiconductor device of claim 1, further comprising contact pads on the substrate, the plurality of pillars mounted to the contact pads.

12. The semiconductor device of claim 11, wherein the plurality of pillars are mounted to active the contact pads.

13. The semiconductor device of claim 11, wherein the plurality of pillars are mounted to inactive the contact pads.

14. The semiconductor device of claim 2, wherein the first semiconductor die is a controller.

15. The semiconductor device of claim 14, wherein the group of one or more second semiconductor die are flash memory die.

16. A semiconductor device, comprising:
a substrate including contact pads;
a first semiconductor die mounted to a surface of the substrate and electrically connected to the substrate;
a plurality of solder pillars soldered to contact pads around the first semiconductor die;
a group of one or more second semiconductor die affixed on the plurality of pillars, the pillars supporting the group of one or more second semiconductor die so as to space the group of one or more second semiconductor die away from the first semiconductor die and electrical connections of the first semiconductor die to the substrate.

17. The semiconductor device of claim 16, wherein the plurality of pillars are made of solder balls.

18. The semiconductor device of claim 16, wherein the plurality of pillars are made of solder paste.

19. The semiconductor device of claim 16, wherein the plurality of pillars are four pillars.

20. The semiconductor device of claim 16, wherein the plurality of pillars are three pillars.

21. The semiconductor device of claim 16, wherein the plurality of pillars are mounted to active the contact pads.

22. The semiconductor device of claim 16, wherein the plurality of pillars are mounted to inactive the contact pads.

23. The semiconductor device of claim 16, wherein the first semiconductor die is a controller.

24. The semiconductor device of claim 23, wherein the group of one or more second semiconductor die are flash memory die.

25. A semiconductor device, comprising:
a substrate;
a first semiconductor die mounted to a surface of the substrate and electrically connected to the substrate;
a plurality of pillars having a first surface affixed to the substrate around the first semiconductor die and a second surface spaced away from the substrate;
a group of one or more second semiconductor die, a semiconductor die of the group of one or more second semiconductor die including a layer of die attach film on a surface of the semiconductor die, the group of one or more second semiconductor die affixed to the substrate by the second surfaces of the plurality of pillars embedding in the die attach film on the surface of the semiconductor die of the group of one or more semiconductor die, the pillars supporting the group of one or more second semiconductor die with a space between the group of one or more second semiconductor die and the first semiconductor die including electrical connections of the first semiconductor die to the substrate.

26. The semiconductor device of claim 25, wherein the second surface of the plurality of pillars has a flat, rounded, jagged, edged or irregular surface shape.

27. The semiconductor device of claim 25, further comprising molding compound, the molding compound securing the group of one or more second semiconductor die in relation to the substrate.

28. The semiconductor device of claim 25, wherein the plurality of pillars are made of solder.

29. The semiconductor device of claim 25, further comprising contact pads on the substrate, the plurality of pillars mounted to the contact pads.

30. The semiconductor device of claim 25, wherein the first semiconductor die is a controller.

31. The semiconductor device of claim 30, wherein the group of one or more second semiconductor die are flash memory die.
